(19) United States
(12) Patent Application Publication
(10) Pub. No.: US 2012/0001324 A1
(43) Pub. Date: Jan. 5, 2012

(54) SEMICONDUCTOR DEVICE AND METHOD FOR MANUFACTURING THE SAME

(75) Inventors: Hideo AOKI, Yokohama-shi (JP); Hideko Mukaida, Kunitachi-shi (JP); Masatoshi Fukuda, Yokohama-shi (JP); Yasuhiro Koshio, Kawasaki-shi (JP); Hiroshi Watabe, Hino-shi (JP)

(73) Assignee: Kabushiki Kaisha Toshiba, Tokyo (JP)

(21) Appl. No.: 13/175,247

(22) Filed: Jul. 1, 2011

(30) Foreign Application Priority Data
Jul. 2, 2010 (JP) 2010-151940

(51) Int. Cl. H01L 23/498; H01L 21/50

(52) U.S. Cl. 257/737; 438/107; 257/778; 257/E23.068; 257/E21.499

(57) ABSTRACT

In one embodiment, a semiconductor device includes a circuit substrate, and first and second semiconductor chips mounted on it. The first semiconductor chip and the second semiconductor chip are flip-chip connected, and an underfill resin is filled between them. The underfill resin has a fillet portion. A thickness T1 of the first semiconductor chip and a thickness T2 of the second semiconductor chip satisfy a relationship of T1/(T1+T2)≦0.6.

### CROSS-REFERENCE TO RELATED APPLICATION

This application is based upon and claims the benefit of priority from Japanese Patent Application No. 2010-151940, filed on Jul. 2, 2010; the entire contents of which are incorporated herein by reference.

### FIELD

Embodiments described herein relate generally to a semiconductor device and a method for manufacturing the same.

### BACKGROUND

To realize a semiconductor device with its size reduced and provided with high functionality, a package structure (COC (Chip on Chip) structure), which has plural semiconductor chips stacked and sealed in one package, is put to practical use. The COC package is applied to a structure or the like which has memory and logic chips stacked, and its practical realization as a SIP (System in Package) type semiconductor device is being performed. Wire bonding is generally applied for connection of the stacked semiconductor chips, but application of flip chip connection is under consideration in order to speed up an information transmission rate, to improve information-processing capability, and the like.

In a case where the flip chip connection is applied to the connection of the chips in the COC package, for example, a first semiconductor chip is mounted on a wiring board, and the electrodes mounted on the top surface of the first semiconductor chip and the electrodes mounted on the bottom surface of a second semiconductor chip mounted on it are electrically and mechanically connected via solder bumps. The space between the upper and lower semiconductor chips is filled with an underfill resin to improve connection reliability and the like. When the flip chip connection is applied to the COC package, a stress tends to concentrate on an end portion of the underfill resin having a fillet shape due to a difference of thermal expansion coefficient between the semiconductor chip and the underfill resin, and the like. And the stress concentration becomes a factor of separating the underfill resin.

### BRIEF DESCRIPTION OF THE DRAWINGS

FIG. 1 is a sectional view showing a semiconductor device according to a first embodiment.

FIG. 2 is a sectional view showing a part of the semiconductor device shown in FIG. 1 in a magnified fashion.

FIG. 3A and FIG. 3B are views showing results of stress simulation of a COC package (two-layered package).

FIG. 4 is a sectional view showing a semiconductor device according to a second embodiment.

FIG. 5 is a sectional view showing a semiconductor device according to a third embodiment.

FIG. 6 is a sectional view showing a semiconductor device according to a fourth embodiment.

### DETAILED DESCRIPTION

In one embodiment, there is provided a semiconductor device including a circuit substrate, a first semiconductor chip mounted on the circuit substrate, a second semiconductor chip stacked on the first semiconductor chip and flip-chip connected to the first semiconductor chip, and an underfill resin filled between the first semiconductor chip and the second semiconductor chip and having a fillet portion on an outer peripheral portion. The first semiconductor chip has a thickness T1, and the second semiconductor chip has a thickness T2. The first and second semiconductor chips satisfy a condition of T1/(T1+T2)≦0.6.

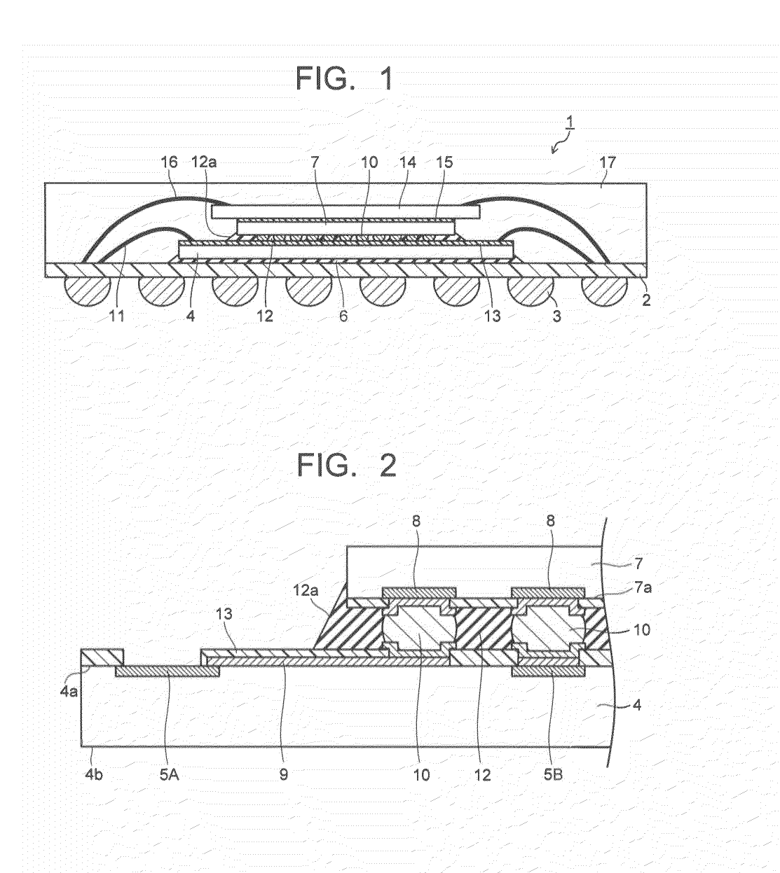

A semiconductor device of an embodiment is described below with reference to the drawings. FIG. 1 is a sectional view showing a semiconductor device having a COC package structure according to a first embodiment, and FIG. 2 is a sectional view showing a part of the semiconductor device shown in FIG. 1 in a magnified fashion. The semiconductor device 1 shown in FIG. 1 and FIG. 2 has a wiring board 2. The wiring board 2 is appropriate when it has a chip mounting portion and a circuit portion, and one having a wiring network (not shown) formed on a surface and within an insulating substrate is used. As the insulating substrate configuring the wiring board 2, a resin substrate, a ceramics substrate, a glass substrate or the like is used. As the wiring board 2, there is used, for example, a multilayer printed circuit board using glass-epoxy resin, BT resin (bismaleimide triazine resin), or the like.

The chip mounting portion is formed on the top surface of the wiring board 2, and external connection terminals 3 such as solder balls are disposed on the bottom surface. A first semiconductor chip 4 is mounted on the chip mounting portion of the wiring board 2. The first semiconductor chip 4 has electrode pads 5 (5A and 5B) which are disposed on a first surface (circuit surface) 4a. A second surface (back surface) 4b of the first semiconductor chip 4 is bonded to the wiring board 2 via an adhesive layer 6 such as a die attach material. A second semiconductor chip 7 is stacked on the first semiconductor chip 4. The second semiconductor chip 7 has electrode pads 8 which are disposed on a first surface (circuit surface) 7a.

For connection between the first semiconductor chip 4 and the second semiconductor chip 7, the flip chip connection is applied. The electrode pads 5 of the first semiconductor chip 4 have first electrode pads 5A which are arranged on a peripheral region of the first surface 4a and second electrode pads 5B which are arranged on a region (chip mounting region) of the first surface 4a where the second semiconductor chip 7 is mounted. A part of the first electrode pads 5A is rewired to the chip mounting region by a rewiring layer 9 which is formed of a Cu wiring layer or the like. One end portion of the rewiring layer 9 is electrically connected to the first electrode pad 5A, and the other end portion is arranged in the chip mounting region.

The second electrode pad 5B arranged on the chip mounting region of the first semiconductor chip 4 and the end portion of the rewiring layer 9 arranged on the chip mounting region are electrically and mechanically connected to the electrode pads 8 disposed on the first surface 7a of the second semiconductor chip 7 via bump electrodes 10. The first electrode pad 5A of the first semiconductor chip 4 is electrically connected to the wiring network of the wiring board 2 via a bonding wire (metal wire) 11 such as an Au wire. At least part of the first electrode pads 5A is connected to the wiring board 2 via the bonding wire 11 and connected to the second semiconductor chip 7 via the rewiring layer 9 and the bump electrode 10.

The bump electrodes 10 are formed of solder bumps which are formed on at least one of the electrode pads 5 of the first semiconductor chip 4 and the electrode pads 8 of the second semiconductor chip 7. The individual solder bumps are connected or the solder bumps and the electrode pads (5 and 8) are connected to form the bump electrodes 10 which electrically and mechanically connect the first semiconductor chip 4 and the second semiconductor chip 7. For the semiconductor device 1 of the first embodiment, for example, the fine bump electrodes 10 made of an Sn—Cu alloy having height of 30 μm and a formation pitch of 60 μm is applied.

An underfill resin 12 is filled in the space between the first semiconductor chip 4 and the second semiconductor chip 7. For the underfill resin 12, for example, epoxy resin, acrylic resin, silicone resin, polyimide resin or the like is used, and it is general to use the epoxy resin containing a filler such as silica powder. The outer peripheral portion of the underfill resin 12 has a fillet shape. The underfill resin 12 is partly squeezed out of the space between the first semiconductor chip 4 and the second semiconductor chip 7 to cover the end face (side face) of the second semiconductor chip 7. The squeezed-out portion of the underfill resin 12 forms a fillet portion 12a.

The first surface 4a of the first semiconductor chip 4 is provided with a stress relaxing layer 13 which relaxes the stress generated when the underfill resin 12 is subjected to thermal curing or a thermal cycle test (TCT). When the stress relaxing layer 13 has a modulus of elasticity smaller than that of silica (SiOx), silicon nitride (SiNx) or the like which forms the insulating layer of the semiconductor chip 4, a stress-relaxing effect can be obtained. The stress relaxing layer 13 is preferably formed of a material having a modulus of elasticity of 30 GPa or less. As a constituent material of the stress relaxing layer 13, insulating resin such as polyimide resin, BCB (benzocyclobutane) resin, silicone resin, epoxy resin or the like can be used.

When the stress relaxing layer 13 is formed of an insulating resin material, the rewiring layer 9 which rewires the first electrode pad 5A of the first semiconductor chip 4 can be formed within it. When the rewiring layer 9 is formed on the first surface 4a of the first semiconductor chip 4 and the rewiring layer 9 is covered by the insulating resin layer which functions as the stress relaxing layer 13, flexibility of the connection position of the first semiconductor chip 4 and the second semiconductor chip 7 is improved. In addition, since the number of terminals to be flip-chip connected is not restricted, flexibility of the connected structure of the first semiconductor chip 4 and the second semiconductor chip 7 can be improved substantially. The first semiconductor chip 4 is not limited to one which has the electrode pad 5A to be rewired.

A third semiconductor chip 14 is bonded onto the second semiconductor chip 7 via an adhesive layer 15. The electrode pad (not shown) disposed on a circuit surface of the third semiconductor chip 14 is electrically connected to the wiring network of the wiring board 2 via a bonding wire 16. The combination of the first to third semiconductor chips 4, 7 and 14 is not particularly restricted, but there is, for example, a combination that the first and third semiconductor chips 4 and 14 are memory chips and the second semiconductor chip 7 is a logic chip such as a processor.

A sealing resin layer 17 which is formed of, for example, epoxy resin is molded on the surface of the wiring board 2 on which the first, second and third semiconductor chips 4, 7 and 14 are mounted. The semiconductor chips 4, 7 and 14 are integrally sealed together with the bonding wires 11 and 16 and the like by the sealing resin layer 17. Thus, the semiconductor device 1 having a COC package structure is configured. It is to be understood that the semiconductor chips 4, 7 and 14 are not limited to the above-described memory chip and logic chip, but it may have partly a silicon interposer or the like.

Meanwhile, when a structure has a semiconductor chip flip-chip connected to a wiring board having a conventional resin substrate, one side of an underfill resin is bonded to the resin substrate. Since the stress generated when the underfill resin is subjected to the thermal curing or heat cycle test is relaxed by the resin substrate, the underfill resin is hard to separate. On the other hand, when the flip chip connection is applied to the connection between the semiconductor chips 4 and 7 of the COC package, both sides of the underfill resin 12 are bonded to the semiconductor chips 4 and 7 having high rigidity, and contraction of the underfill resin 12 is restricted by the semiconductor chips 4 and 7 having a small thermal expansion coefficient.

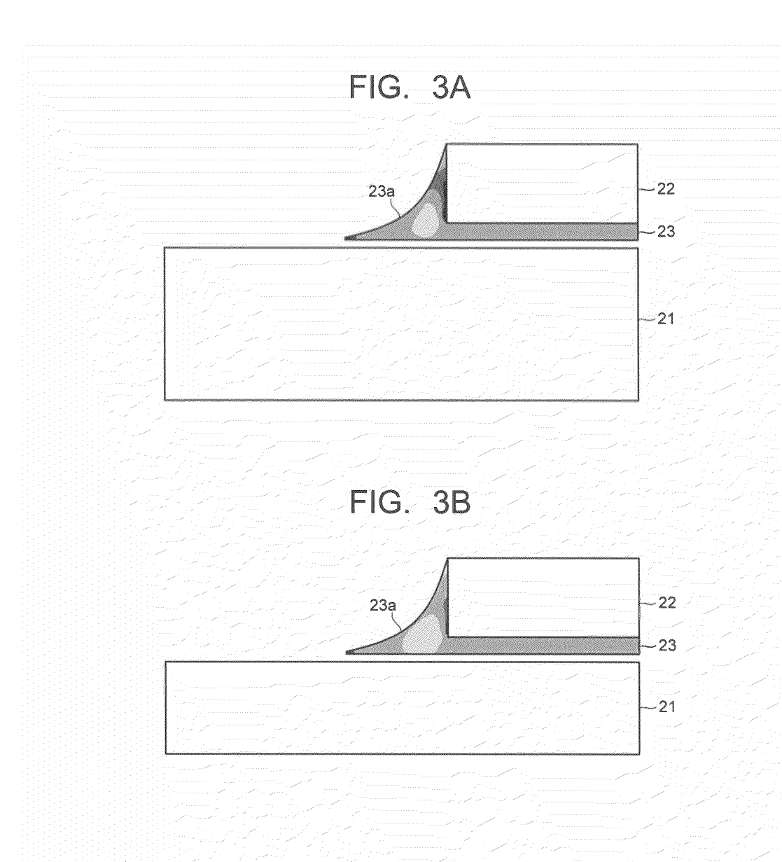

When the COC package is used for the thermal cycle test (TCT), the stress generated at the time of the TCT concentrates on an end portion of the underfill resin 12. Stress simulation was executed on the COC package (two-layered package) having two semiconductor chips flip-chip connected to check what stress is generated by a temperature change. The obtained results are shown in FIG. 3A and FIG. 3B. FIG. 3A and FIG. 3B are views schematically showing the results of stress simulation of the COC package (two-layered package).

FIG. 3A shows the result of simulation when a lower-stage chip 21 has a thickness of 250 μm and an upper-stage chip 22 has a thickness of 130 μm. FIG. 3B shows the result of simulation when the lower-stage chip 21 has a thickness of 150 μm and the upper-stage chip 22 has a thickness of 130 μm. FIG. 3A and FIG. 3B show the stress generated in an underfill resin 23 in gray gradation, indicating that a dark portion is a high stress region, and a light portion is a low stress region.

In the COC package of FIG. 3A, a lot of stress is generated in a region in contact with the side face of the upper-stage chip 22 of a fillet portion 23a of the underfill resin 23. As apparent from comparison between FIG. 3A and FIG. 3B, it was found that the stress depends on the thickness of the lower-stage chip 21 and becomes large as the thickness of the lower-stage chip 21 increases. It is apparent from FIG. 3B that the high stress region becomes small in size when the thickness of the lower-stage chip 21 is decreased, and the stress generated at the time of the TCT is relaxed. Based on the results of stress simulation, the stress simulation of the semiconductor device (three-layered package) 1 shown in FIG. 1 was executed. The results are shown in Table 1.

TABLE 1

| | First Chip | Second Chip | Third Chip | | High Stress |
|---|---|---|---|---|---|
| | Thickness | Thickness | Thickness | | Region |
| | (T1)[μm] | (T2)[μm] | (T3)[μm] | T1/(T1 + T2) | Length[μm] |
| Sample 1 | 150 | 130 | 100 | 0.54 | 25 |
| Sample 2 | 250 | 130 | 100 | 0.66 | 40 |
| Sample 3 | 250 | 130 | none | 0.66 | 60 |

In Table 1, T1 represents a thickness of a lower-stage chip (first semiconductor chip 4) between the flip-chip connected semiconductor chips 4 and 7, T2 represents a thickness of an upper-stage chip (second semiconductor chip 7), and T3 represents a thickness of the third semiconductor chip 14 stacked on it. The high stress region length in Table 1 is a length of the region where a stress value became 35 MPa or more by the stress simulation, and the length of the high stress region generated at a portion in contact with a side surface of the upper-stage chip 22 of the fillet portion 23a as shown in FIG. 3A and FIG. 3B.

It is apparent from Table 1 that the generation of the high stress region can be suppressed by determining that a ratio (T1/(T1+T2)) of the thickness T1 of the first semiconductor chip 4 to the sum (T1+T2) of the thickness of the first and second semiconductor chips 4 and 7 is 0.6 or less. Generation of the high stress region can be further suppressed by stacking the third semiconductor chip 14 on the flip-chip connected first and second semiconductor chips 4 and 7. Therefore, separation of the underfill resin 12 starting from the fillet portion 12a can be suppressed.

The sum (T1+T2) of the thickness of the flip-chip connected semiconductor chips 4 and 7 is relevant to the warp of the two semiconductor chips 4 and 7, and when the sum value becomes large, the warp of the semiconductor chips 4 and 7 becomes small. The thickness T1 of the lower-stage chip (first semiconductor chip 4) is a factor determining its rigidity (softness), and it is considered that the thickness T1 affects largely on a deformation amount of the underfill resin 12, particularly a deformation amount of a lower part of the fillet portion 12a. Therefore, the stress concentration on the fillet portion 12a of the underfill resin 12 can be relaxed by decreasing the ratio (T1/(T1+T2)) of the thickness T1 of the lower-stage chip (first semiconductor chip 4) to the sum (T1+T2) of the thickness of the flip-chip connected semiconductor chips 4 and 7.

That is, the stress concentrating on the fillet portion 12a of the underfill resin 12 is relaxed by determining the value of T1/(T1+T2) to be 0.6 or less, and it becomes possible to suppress the separation of the underfill resin 12 starting from the fillet portion 12a. But, when the value of T1/(T1+T2) is decreased excessively, it is hard to secure the first semiconductor chip 4 having a practical thickness, and the value of T1/(T1+T2) is preferably set to 0.02 or more, and more preferably to 0.025 or more. The specific thickness T1 of the first semiconductor chip 4 is preferably determined to be in a range of 50 to 200 μm considering the maintenance of function as the semiconductor chip and the relaxing effect of the stress upon the fillet portion 12a.

As described above, the third semiconductor chip 14 is stacked on the second semiconductor chip 7 in addition to the determination that the thickness ratio (T1/(T1+T2)) of the flip-chip connected semiconductor chips 4 and 7 is 0.6 or less, so that the warp of the flip-chip connected semiconductor chips 4 and 7 is further reduced. Therefore, the stress concentration on the fillet portion 12a of the underfill resin 12 can be further relaxed. The semiconductor device 1 produced with the thickness of the first, second and third semiconductor chips 4, 7 and 14 varied was subjected to the thermal cycle test (TCT) at 125° C. to −55° C. The results are shown in Table 2.

TABLE 2

| | First Chip | Second Chip | Third Chip | | |
|---|---|---|---|---|---|
| | Thickness | Thickness | Thickness | | TCT |
| | (T1)[μm] | (T2)[μm] | (T3)[μm] | T1/(T1 + T2) | Result |
| Example 1 | 150 | 130 | 100 | 0.54 | OK |
| Example 2 | 150 | 110 | 100 | 0.58 | OK |
| Comparative | 200 | 130 | 100 | 0.61 | NG |
| Example 1 | | | | | |

The semiconductor devices of Examples 1 and 2 in which the flip-chip connected semiconductor chips 4 and 7 had a thickness ratio (T1/(T1+T2)) of 0.6 or less did not have separation of the underfill resin 12 even after a 500-cycle TCT. Meanwhile, the semiconductor device of Comparative Example 1 in which the semiconductor chips 4 and 7 had a thickness ratio (T1/(T1+T2)) of more than 0.6 was found by cross-section observation that the fillet portion 12a of the underfill resin 12 and the side face of the second semiconductor chip 7 were separated from each other after the 500-cycle TCT. The semiconductor device of Comparative Example 1 was also found that connection points based on the bump electrodes 10 were also broken partly, resulting in an electrical failure.

As described above, when the ratio (T1/(T1+T2)) of the thickness T1 of the lower-stage chip (first semiconductor chip 4) to the sum (T1+T2) of the thickness of the flip-chip connected semiconductor chips 4 and 7 is determined to be 0.6 or less, the stress concentration on the fillet portion 12a of the underfill resin 12 at the time of the TCT can be relaxed. Therefore, the separation starting from the fillet portion 12a of the underfill resin 12 can be suppressed. It is also effective to provide the stress relaxing layer 13 on the top surface of the lower-stage chip (first semiconductor chip 4) in order to relax the stress concentration on the fillet portion 12a. Thus, the stress concentration on the fillet portion 12a can be further relaxed, and the reliability of the semiconductor device 1 can be improved.

In addition, it is also effective to stack the third semiconductor chip 14 on the flip-chip connected semiconductor chips 4 and 7. Stacking the third semiconductor chip 14 reduces the warp of the flip-chip connected semiconductor chips 4 and 7, and the stress applied to the fillet portion 12a of the underfill resin 12 can be further relaxed. The chip member to be stacked on the flip-chip connected semiconductor chips 4 and 7 is not limited to the semiconductor chip but may be a chip member having the same rigidity as the semiconductor chip. For example, a chip member made of silicon, GaN, GaAs, glass or the like can be applied.

The adhesive layer 15 for adhering the chip member such as the third semiconductor chip 14 onto the second semiconductor chip 7 is preferably made of an insulating resin material having a stress-relaxing effect similar to the stress relaxing layer 13 which is disposed on the first surface 4a of the first semiconductor chip 4. The adhesive layer 15 which also serves as a stress relaxing layer is preferably formed of insulating resin having a modulus of elasticity of 30 GPa or less as described above. When an adhesive layer and stress relaxing layer 15 formed of the above insulating resin is applied, the stress applied to the fillet portion 12a of the underfill resin 12 can also be relaxed.

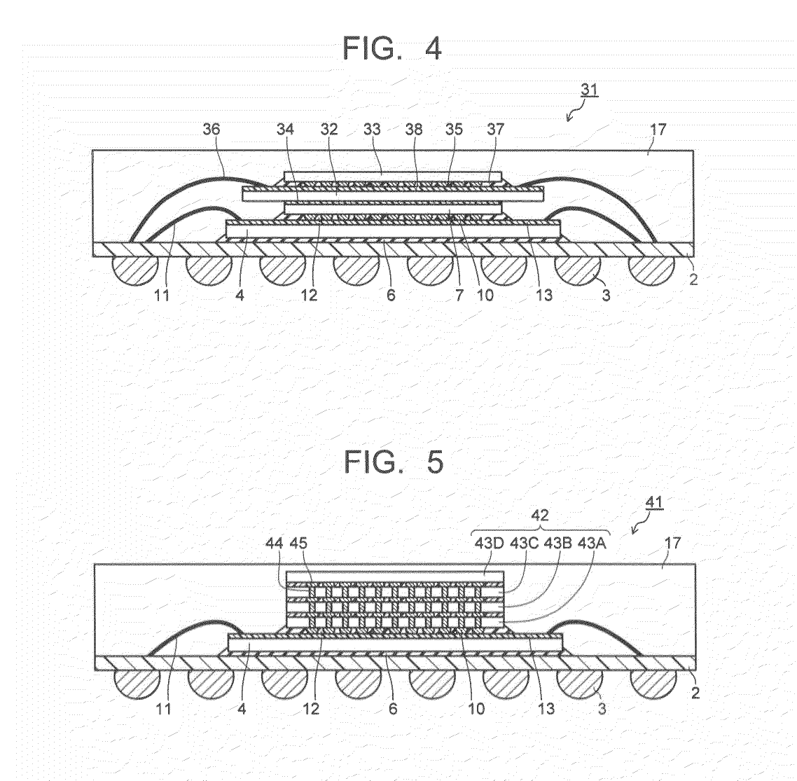

FIG. 4 shows a semiconductor device 31 according to a second embodiment. Like component parts corresponding to those of the semiconductor device 1 shown in FIG. 1 are denoted by like reference numerals, and their descriptions will be partly omitted. In the semiconductor device 31 shown in FIG. 4, the first and second semiconductor chips 4 and 7 which are flip-chip connected in the same manner as in the first embodiment are mounted on the wiring board 2. Flip-chip connected third and fourth semiconductor chips 32 and 33 are mounted thereon.

The third semiconductor chip 32 is bonded onto the second semiconductor chip 7 via an adhesive layer 34. It is preferable as described above that the adhesive layer 34 also serves as a stress relaxing layer. The fourth semiconductor chip 33 is flip-chip connected onto the third semiconductor chip 32 via bump electrodes 35. The electrode pads of the third semiconductor chip 32 are partly connected electrically to the wiring network of the wiring board 2 via bonding wires 36. An underfill resin 37 is filled in the space between the third semiconductor chip 32 and the fourth semiconductor chip 33.

Similar to the first embodiment, the thickness T1 of the first semiconductor chip 4 and the thickness T2 of the second semiconductor chip 7 satisfy a relationship, (T1/(T1+T2))≦0.6. The stress relaxing layer 13 is disposed on the circuit surface of the first semiconductor chip 4. In addition, the third semiconductor chip 32 is stacked on the second semiconductor chip 7 via the adhesive layer 34 which also serves as a stress relaxing layer. Thus, the stress concentration on the fillet portion 12a of the underfill resin 12 is relaxed, and it becomes possible to suppress the separation starting from the fillet portion 12a.

It is also preferable that the third and fourth semiconductor chips 32 and 33 have the same structure (thickness, stress relaxing layer, etc.) as the first and second semiconductor chips 4 and 6. That is, it is preferable that the thickness T3 of the third semiconductor chip 32 and the thickness T4 of the fourth semiconductor chip 33 satisfy a relationship (T3/(T3+T4))≦0.6, and also a relationship 0.02≦(T3/(T3+T4)≦0.6 similar to the relationship between the thickness T1 of the first semiconductor chip 4 and the thickness T2 of the second semiconductor chip 7. The third semiconductor chip 32 preferably has a stress relaxing layer 38 which is disposed on the circuit surface of the third semiconductor chip 32.

FIG. 5 shows a semiconductor device 41 according to a third embodiment. Like component parts corresponding to those of the semiconductor device 1 shown in FIG. 1 are denoted by like reference numerals, and their descriptions will be partly omitted. The semiconductor device 41 shown in FIG. 5 has the first semiconductor chip 4 mounted on the wiring board 2 via the adhesive layer 6 in the same manner as in the first embodiment. A stack chip 42, which is stacked by applying Si through-via technology, is mounted on the first semiconductor chip 4.

The stack chip 42 has four semiconductor chips 43A, 43B, 43C and 43D. The semiconductor chips 43A to 43D are stacked and also electrically connected mutually via through vias 44 and bump electrodes 45. And, the lowermost semiconductor chip 43A in the stack chip 42 is flip-chip connected to the first semiconductor chip 4, which is mounted on the wiring board 2, via the bump electrodes 10. The underfill resin 12 is filled in the space between the first semiconductor chip 4 and the stack chip 42.

The thickness T1 of the first semiconductor chip 4 and the thickness T2 of the lowermost semiconductor chip 43A in the stack chip 42 satisfy a relationship, (T1/(T1+T2))?0.6 similar to the first embodiment. In addition, the stress relaxing layer 13 is disposed on the circuit surface of the first semiconductor chip 4. Thus, the stress concentration on the fillet portion 12a of the underfill resin 12 is relaxed, so that it becomes possible to suppress the separation starting from the fillet portion 12a.

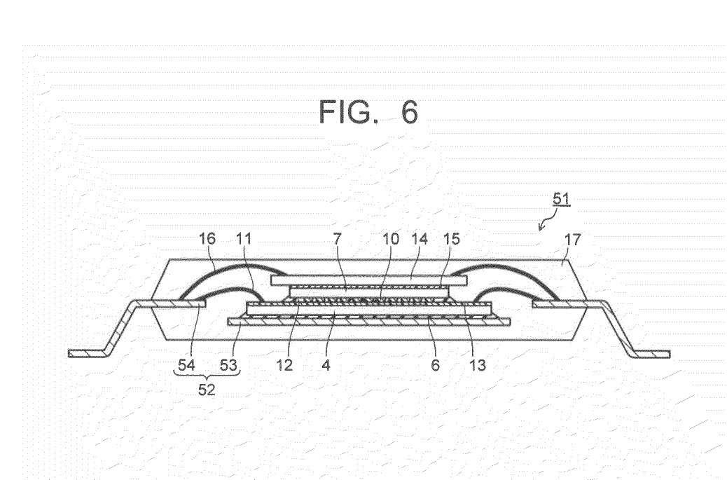

FIG. 6 shows a semiconductor device 51 according to a fourth embodiment. Like component parts corresponding to those of the semiconductor device 1 shown in FIG. 1 are denoted by like reference numerals, and their descriptions will be partly omitted. The semiconductor device 51 shown in FIG. 6 has the first semiconductor chip 4 mounted on a mount portion 53 of a lead frame 52 via the adhesive layer 6. The electrode pads of the first semiconductor chip 4 are partly connected electrically to a lead portion 54 of the lead frame 52 via the bonding wires 11.

The semiconductor device 51 shown in FIG. 6 has the same structure as in the first embodiment except that the lead frame 52 is applied instead of the wiring board 2 as the circuit substrate. That is, the second semiconductor chip 7 is flip-chip connected to the first semiconductor chip 4. The third semiconductor chip 14 is stacked on the second semiconductor chip 7. The other structure is also the same as the semiconductor device 1 of the first embodiment.

As described above, the circuit substrate of the semiconductor device having the COC package structure is not limited to the wiring boards 2 described in the first through third embodiments but may also be the lead frame 52 described in the fourth embodiment. That is, the semiconductor devices 1, 31, 41 and 51 of the embodiments are provided with the circuit substrate which comprises the wiring board 2 and the lead frame 52 and can be applied to a semiconductor package (BGA package, LGA package, etc.) using the wiring board 2 and the semiconductor package (TSOP etc.) using the lead frame 52.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a circuit substrate;
a first semiconductor chip, mounted on the circuit substrate, having a thickness T1;
a second semiconductor chip, stacked on the first semiconductor chip, having a thickness T2 and flip-chip connected to the first semiconductor chip; and
an underfill resin, filled between the first semiconductor chip and the second semiconductor chip, having a fillet portion on an outer peripheral portion,
wherein the first and second semiconductor chips satisfy a condition of T1/(T1+T2)≦0.6.

2. The semiconductor device according to claim 1,
wherein the first and second semiconductor chips satisfy a condition of 0.02≦T1/(T1+T2)≦0.6.

3. The semiconductor device according to claim 1,
wherein the first semiconductor chip has the thickness T1 in a range of 50 to 200 μm.

4. The semiconductor device according to claim 1,
wherein the first semiconductor chip has a first surface including electrode pads and a stress relaxing layer, and a second surface bonded to the circuit substrate via an adhesive layer, and the second semiconductor chip has a first surface including electrode pads, and
wherein at least part of the electrode pads of the first semiconductor chip is connected to the electrode pads of the second semiconductor chip via bump electrodes.

5. The semiconductor device according to claim 4,
wherein the stress relaxing layer is made of a material having a modulus of elasticity of 30 GPa or less.

6. The semiconductor device according to claim 5,
wherein the stress relaxing layer is made of an insulating resin material.

7. The semiconductor device according to claim 6,
wherein the first semiconductor chip has a wiring layer disposed into the stress relaxing layer.

8. The semiconductor device according to claim 1,
wherein the first semiconductor chip has a first surface including electrode pads and a second surface bonded to the circuit substrate via an adhesive layer, and the second semiconductor chip has a first surface including electrode pads,
wherein the electrode pads of the first semiconductor chip have first electrode pads arranged on a peripheral region of the first surface and second electrode pads arranged on a chip mounting region of the first surface where the second semiconductor chip is mounted, and the first electrode pads are electrically connected to the circuit substrate through metal wires, and at least part of the first electrode pads is rewired to the chip mounting region by a rewiring layer which is disposed on the first surface, and
wherein the second electrode pads and an end portion of the rewiring layer arranged on the chip mounting region are connected to the electrode pads of the second semiconductor chip via bump electrodes.

9. The semiconductor device according to claim 8,
wherein the rewiring layer is disposed into a stress relaxing layer which is arranged on the first surface, and is made of an insulating resin material.

10. A semiconductor device, comprising:
a circuit substrate;
a first semiconductor chip, mounted on the circuit substrate, having a thickness T1;
a second semiconductor chip, stack on the first semiconductor chip, having a thickness T2 and flip-chip connected to the first semiconductor chip;
a chip member stacked on the second semiconductor chip; and
an underfill resin, filled between the first semiconductor chip and the second semiconductor chip, having a fillet portion on an outer peripheral portion,
wherein the first and second semiconductor chips satisfy a condition of T1/(T1+T2)≦0.6.

11. The semiconductor device according to claim 10,
wherein the first and second semiconductor chips satisfy a condition of 0.02≦T1/(T1+T2)≦0.6.

12. The semiconductor device according to claim 10,
wherein the first semiconductor chip has the thickness T1 in a range of 50 to 200 μm.

13. The semiconductor device according to claim 10,
wherein the first semiconductor chip has a first stress relaxing layer disposed on a surface connected to the second semiconductor chip.

14. The semiconductor device according to claim 13,
wherein the chip member is bonded to the second semiconductor chip via a second stress relaxing layer.

15. The semiconductor device according to claim 14,
wherein the first and second stress relaxing layers are made of a material having a modulus of elasticity of 30 GPa or less.

16. The semiconductor device according to claim 10,
wherein the first semiconductor chip has a first surface including electrode pads and a second surface bonded to the circuit substrate via an adhesive layer, and the second semiconductor chip has a first surface including electrode pads,
wherein the electrode pads of the first semiconductor chip have first electrode pads arranged on a peripheral region of the first surface and second electrode pads arranged on a chip mounting region of the first surface where the second semiconductor chip is mounted, and the first electrode pads are electrically connected to the circuit substrate through first metal wires, and at least part of the first electrode pads are rewired to the chip mounting region by a rewiring layer which is disposed on the first surface, and
wherein the second electrode pads and an end portion of the rewiring layer arranged on the chip mounting region are connected to the electrode pads of the second semiconductor chip via bump electrodes.

17. The semiconductor device according to claim 16,
wherein the rewiring layer is disposed into a stress relaxing layer which is arranged on the first surface, and is made of an insulating resin material.

18. The semiconductor device according to claim 17,
wherein the chip member comprises a third semiconductor chip, and
wherein the third semiconductor chip has a first surface including electrode pads and a second surface bonded to the second semiconductor chip via an adhesive layer, and the electrode pads of the third semiconductor chip are electrically connected to the circuit substrate via second metal wires.

19. A method for manufacturing a semiconductor device, comprising:
mounting a first semiconductor chip having a thickness T1 on a circuit substrate;
stacking a second semiconductor chip having a thickness T2 on the first semiconductor chip, the second semiconductor chip being flip-chip connected to the first semiconductor chip; and
filling an underfill resin between the first semiconductor chip and the second semiconductor chip, the underfill resin having a fillet portion on an outer peripheral portion,
wherein the thickness T1 of the first semiconductor chip and the thickness T2 of the second semiconductor chip are controlled to satisfy a condition of T1/(T1+T2)≦0.6.

20. The manufacturing method according to claim 19, further comprising:
stacking a chip member on the second semiconductor chip.
